(19) United States
(12) Patent Application Publication
(10) Pub. No.: US 2013/0043566 A1
(43) Pub. Date: Feb. 21, 2013

(54) SEMICONDUCTOR DEVICE AND FLIP-CHIP PACKAGE

(71) Applicant: Panasonic Corporation, Osaka (JP)

(72) Inventors: Sumiaki NAKANO, Nara (JP); Noriyuki NAGAI, Nara (JP)

(73) Assignee: Panasonic Corporation, Osaka (JP)

(21) Appl. No.: 13/658,660

(22) Filed: Oct. 23, 2012

Related U.S. Application Data
(63) Continuation of application No. PCT/JP2011/005886, filed on Oct. 20, 2011.

(30) Foreign Application Priority Data
Jan. 14, 2011 (JP) 2011-006207

(51) Int. Cl. H01L 23/544

(52) U.S. Cl. 257/620; 257/E23.179

(57) ABSTRACT

A semiconductor device includes a substrate having a circuit formation region, an interlayer insulating film formed on the substrate, a first seal ring formed in the interlayer insulating film to surround the circuit formation region, a first protective film formed on the interlayer insulating film in the circuit formation region and on the first seal ring, and a second protective film formed on the first protective film and inside relative to the first seal ring. The first protective film has a first surface contacting the second protective film, a second surface located directly on the first seal ring, and a third surface connecting the first surface and the second surface together, and an end of the second protective film is located inside relative to the third surface.

### CROSS-REFERENCE TO RELATED APPLICATION

This is a continuation of PCT International Application PCT/JP2011/005886 filed on Oct. 20, 2011, which claims priority to Japanese Patent Application No. 2011-006207 filed on Jan. 14, 2011. The disclosures of these applications including the specifications, the drawings, and the claims are hereby incorporated by reference in their entirety.

### BACKGROUND

In general, when semiconductor devices are fabricated, necessary circuits are integrated in each of a plurality of chip regions provided on a semiconductor substrate in a wafer state. The plurality of the chip regions are separated from one another by a scribe region (or a scribe line) arranged in a grid pattern. A wafer is diced along such a scribe region to separate the wafer into individual chips.

However, when dicing the wafer into individual chips, the chip regions around the scribe line are subjected to mechanical impact, whereby it may affect the separated chips (thus, semiconductor devices). Specifically, cracks or chippings are produced in the dicing cross sections of the semiconductor devices, thereby affecting a circuit formation region of the semiconductor device. Water, ions, etc., included in the outside may affect the circuit formation region of the semiconductor device.

In order to protect the circuit formation region of the semiconductor device from such effects, a protection structure called as a seal ring may be formed inside the portion which is diced, in other words, in the vicinity of the edge of the chip (die). As means for protecting the surface of the semiconductor device, a protective film may be formed in the surface thereof.

An example of such structures includes Japanese Patent Publication No. 2010-206226 (hereinafter referred to as reference 1). Reference 1 will be described hereinafter.

FIG. 11 shows a schematic structure of a semiconductor device 100 in reference 1. The semiconductor device 100 includes a semiconductor substrate 101. On the semiconductor substrate 101, a plurality of layers (three layers in this case), i.e., interlayer insulating films 111a, 111b, and 111c (hereinafter, they may be collectively referred to as an interlayer insulating film 111) are stacked. A circuit formation region 102 in which interconnects, circuits, etc., are formed, and a dicing region 103 in which dicing is performed are provided, and a seal ring 104 is provided between the circuit formation region 102 and the dicing region 103 in the interlayer insulating film 111.

The seal ring 104 serves as a barrier against water having entered from the cross-section of part of the interlayer insulating film 111 exposed by the dicing, and a crack extension generated by stress. The seal ring 104 includes a plurality of sealing layers (each of which is not shown) continuously stacked, and a sealing layer 105 constituting the uppermost layer is made of, e.g., aluminum.

A first protective film 106 made of a silicon nitride film formed by plasma nitriding is formed on the interlayer insulating film 111 so as to cover the sealing layer 105. A second protective film 107 made of a polyimide film is formed on the first protective film 106. The first protective film 106 and the second protective film 107 cover the circuit formation region 102, the seal ring 104, and the dicing region 103.

### SUMMARY

However, in the structure stated above, the shape of the second protective film 107 which is the polyimide film cannot be formed with sufficient shaping accuracy, and peeling may further occur due to such shaping inaccuracy.

In view of the above-described problems, a semiconductor device having a seal ring and a protective film will be obtained as described below to secure shaping accuracy and peel resistance, and to have higher reliability.

The present inventors considered causes of the problems, such as shape variations of the second protective film of the polyimide film, peeling, etc. As a result, they found that the causes of the problems are, if an end of the second protective film is located on or outside the seal ring, shape variations of the second protective film (poor positioning accuracy of the end position, etc.) when forming the second protective film, and shapes of underlying elements, etc. Besides, in order to reduce such problems, they have developed a definition of a structure of the seal ring and the vicinity thereof, such as a positional relationship between the end of the second protective film and the seal ring, etc.

In view of the foregoing, a semiconductor device of the present disclosure includes a substrate having a circuit formation region; an interlayer insulating film formed on the substrate; a first seal ring formed in the interlayer insulating film to surround the circuit formation region; a first protective film formed on the interlayer insulating film in the circuit formation region and on the first seal ring; and a second protective film formed on the first protective film and inside relative to the first seal ring, wherein the first protective film has a first surface contacting the second protective film,a second surface located directly on the first seal ring, and a third surface connecting the first surface and the second surface together, and an end of the second protective film is located inside relative to the third surface.

According to such a semiconductor device, the effect caused by the existence of the seal ring is reduced, thereby making it possible to improve shaping accuracy and peeling resistance.

A first opening may be formed in the first protective film to be located directly on the first seal ring.

A second opening may be formed in the first protective film to be located outside the first seal ring.

Such a structure can block a transmission of impact, stress, etc., to the circuit formation region from the outside of the seal ring via the first protective film as a route of the transmission at a time of dicing, etc. This can reliably prevent deterioration of reliability, moisture resistance, etc., of the semiconductor device.

At least one second seal ring may be formed in the interlayer insulating film to surround the first seal ring.

With such a structure, a plurality of the seal rings surround the circuit formation region, thereby more significantly protecting the circuit formation region from water having entered from the cross-section of part of the interlayer insulating film, and a crack extension generated by stress. The first seal ring is located in the innermost part (closest to the circuit formation region), and the end of the second protective film is located inside relative to the third surface located on the first seal ring, and therefore, the shaping accuracy and the peeling resistance of the second protective film is reliably improved.

The second opening may be located between the first seal ring and the at least one second seal ring.

The second opening may be formed to pass through the first protective film.

Such a structure more reliably blocks the route of the transmission of impact, stress, etc.

The second opening may be formed so as not to reach part of the interlayer insulating film located directly under the first protective film.

Such a structure, even if circuits, interconnects, etc., are formed in the interlayer insulating film, can avoid exposing such circuits, interconnects, etc. For example, interconnects for inspection, etc., may be provided outside the seal ring, and its exposure is preferably avoided. Exposure of the sealing layer constituting the seal ring can be also avoided.

The second opening may be located to surround the first seal ring.

The second opening may be located to continuously surround the first seal ring.

Such a structure more reliably blocks the route of the transmission of impact, stress, etc.

A first opening may be formed in the first protective film to be located directly on the first seal ring, a second opening may be formed in the first protective film to be located outside the first seal ring, and the second opening may be deeper than the first opening.

A third opening may be formed in the first protective film to be located outside the second seal ring.

Such a structure more reliably blocks the route of the transmission of impact, stress, etc.

The third opening may be deeper than the second opening.

The second opening may be deeper than the third opening.

The second seal ring may be an outermost seal ring.

An opening may be located directly on each of the first seal ring and the at least one second seal ring in the first protective film.

The first seal ring may include a plurality of sealing layers which are stacked, and a cap layer formed on the uppermost sealing layer to be connected thereto.

Such a structure can prevent reduced protection of the semiconductor device by sealing due to oxidation and corrosion of the sealing layer located under the cap layer. This advantage is more significantly achieved if the cap layer is made of a material having an oxidation resistance greater than that of the sealing layers located directly thereunder.

For example, the sealing layer may be made of copper (Cu), and the cap layer may be made of aluminum (Al).

A width of the cap layer may be wider than that of the uppermost sealing layer.

Such a structure can cover the uppermost sealing layer with the cap layer, and therefore, the cap layer more significantly protects the seal ring.

The end of the second protective film may be located between the third surface and the circuit formation region.

Such a structure can protect the circuit formation region by the second protective film, and improve the shaping accuracy and the peeling resistance of the second protective film.

Part of the first protective film on which the end of the second protective film is located may have an upper surface which is substantially flat.

Such a structure can more reliably improve the shaping accuracy and the peeling resistance of the second protective film

The semiconductor device may include a separation region between the first seal ring and the circuit formation region so as not to form a circuit and an interconnect therein, wherein an upper surface of part of the first protective film located in the separation region may be substantially flat, and the end of the second protective film may be located on the separation region.

Such a structure secures a distance between the seal ring and the circuit formation region, thereby making it possible to significantly protect the circuit formation region from moisture, a crack, etc. A region in which the end of the second protective film can be located becomes wider, and therefore, the second protective film can be accurately formed such that the end thereof is located in a proper region, even if there are positioning variations when forming the second protective film.

The interlayer insulating film may include a low dielectric constant film.

The interlayer insulating film may include an extremely low dielectric constant film.

In other words, the interlayer insulating film may be made of the low dielectric constant film (low-k film) or the extremely low dielectric constant film (extremely low-k (ELK) film), or may have a layered structure including the low dielectric constant film or the extremely low dielectric constant film. This structure can achieve speeding up, and reducing energy consumption of the semiconductor device.

The semiconductor device may include a plurality of bumps arranged in a grid pattern on a back surface of the substrate and under the circuit formation region.

Such a structure can achieve a semiconductor device which includes many bumps in the circuit formation region and which can be flip-chip mounted.

The bumps may be arranged only under the circuit formation region, and not arranged under the seal ring.

The first protective film may be made of a silicon nitride film, and the second protective film may be made of a polyimide film.

These films may be made of such materials, for example, as stated above.

A surface of the second protective film may be located to be higher than the second surface of the first protective film.

A flip-chip package of the present disclosure has a structure in which any one of the semiconductor devices of the present disclosure is flip-chip mounted on a mounting substrate.

Such a flip-chip package has the mounted semiconductor device having higher reliability, and can be mounted with higher density.

According to the techniques of the present disclosure, a semiconductor device having a seal ring and a protective film can be obtained to improve shaping accuracy and peel resistance of the protective film, etc., for protecting surfaces of chips to have higher reliability.

### BRIEF DESCRIPTION OF THE DRAWINGS

FIGS. 1A and 1B are, respectively, a cross-sectional view and a plan view schematically showing an example semiconductor device of an embodiment of the present disclosure.

FIG. 2 is a cross-sectional view schematically showing a modified example of the example semiconductor device of the embodiment of the present disclosure.

FIG. 3 is a cross-sectional view schematically showing a modified example of the example semiconductor device of the embodiment of the present disclosure.

FIG. 4 is a cross-sectional view schematically showing a modified example of the example semiconductor device of the embodiment of the present disclosure.

FIGS. 5A and 5B are, respectively, a cross-sectional view and a plan view schematically showing schematically showing a modified example of the example semiconductor device of the embodiment of the present disclosure.

FIG. 6 is a cross-sectional view schematically showing a modified example of the example semiconductor device of the embodiment of the present disclosure.

FIG. 7 is a cross-sectional view schematically showing a modified example of the example semiconductor device of the embodiment of the present disclosure.

FIG. 8 is a cross-sectional view schematically showing a modified example of the example semiconductor device of the embodiment of the present disclosure.

FIG. 9 is a cross-sectional view schematically showing bumps provided in the example semiconductor device of the embodiment of the present disclosure.

FIG. 10 is a cross-sectional view schematically showing the example semiconductor device of the embodiment of the present disclosure which is flip-chip mounted using the bumps.

FIG. 11 is a cross-sectional view schematically showing a semiconductor device in the background.

### DETAILED DESCRIPTION

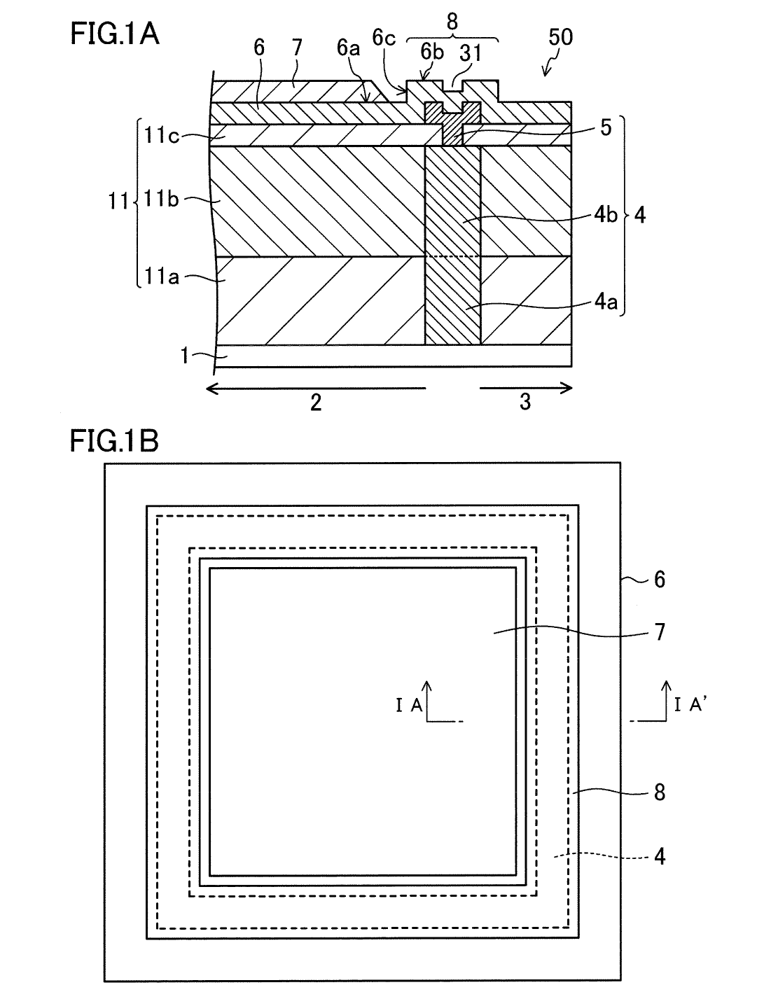

A semiconductor device of the present disclosure will be described in detail hereinafter with reference to the accompanying drawings. FIGS. 1A and 1B are, respectively, a cross-sectional view and a plan view schematically showing an example semiconductor device 50, and FIG. 1A is the cross-sectional view taken along the line Ia-Ia′ of FIG. 1B which is the plan view.

As shown in FIG. 1A, the semiconductor device 50 is formed using a semiconductor substrate 1 which is a silicon substrate, etc. On the semiconductor substrate 1, an interlayer insulating film 11 is formed to have a structure in which a plurality of layers (three layers in the example of FIG. 1), i.e., insulating films 11a, 11b, and 11c are stacked. A circuit formation region 2 for forming interconnects, circuits, etc., is provided in the center of the semiconductor device 50, and a dicing region 3 is provided outside the circuit formation region 2 to surround the vicinity of the circuit formation region 2.

Interconnects and contact portions (not shown) in the interlayer insulating film 11 of the circuit formation region 2 are formed to be electrically connected to elements, such as a transistor, etc., formed on the semiconductor substrate 1.

A seal ring 4 is formed between the circuit formation region 2 and the dicing region 3 to be embedded in the interlayer insulating film 11. The seal ring 4 has a structure in which sealing layers 4a and 4b and a cap layer 5 are continuously stacked, where the sealing layers 4a and 4b are formed by using steps of forming the contact portions and the interconnects formed in each of the films of the interlayer insulating film 11, and the cap layer 5 is formed in the uppermost part of the seal ring 4.

The sealing layers 4a and 4b are made of, e.g., copper (Cu), and a barrier metal layer (not shown) made of, e.g., TaN is formed between the sealing layer and the interlayer insulating film 11. This prevents a material constituting the sealing layer (the contact portions and interconnects) from directly contacting the interlayer insulating film 11.

In the uppermost part of the seal ring 4, the cap layer 5 may be formed in an opening of the interlayer insulating film 11 (more specifically, an opening of the insulating film 11c) as a sealing layer formed to have a protrusion (having a shape protruding upwardly) with respect to the upper surface of the interlayer insulating film 11. The cap layer 5 is formed to cover the opening.

A first protective film 6 is formed on the interlayer insulating film 11 to cover the cap layer 5, the circuit formation region 2, and the dicing region 3. The first protective film 6 is preferably made of a silicon nitride film formed by plasma nitriding, and preferably has a thickness of approximately 0.6 μm. The material and thickness are not limited to the above material and above thickness.

The upper surface of the cap layer 5 is recessed along the opening of the insulating film 11c, and on the upper surface of the cap layer 5, the upper surface of the first protective film 6 is recessed so that an opening 31 is formed.

Besides, a second protective film 7 is formed on the first protective film 6. Regarding the material and thickness of the second protective film 7, it is preferably made of, e.g., polyimide, and preferably has a thickness of approximately 5 μm. The material and thickness are not limited to the above material and above thickness.

If the second protective film 7 is formed to have an end on or outside the seal ring 4 (the dicing region 3), the present inventors have found that the second protective film 7 is not formed with sufficient shaping accuracy, and peeling occurs due to such shaping inaccuracy. The problems are affected by shape variations of the second protective film 7 (poor positioning accuracy of the end position, etc.), and the shapes of the underlying elements.

As a specific example, suppose that the width of the seal ring 4 (the cap layer 5) is 4 μm, the width of a rising portion 8 of the first protective film 6 covering the seal ring 4 is 10 μm. Suppose the end of the second protective film 7 is located on the rising portion 8 of the first protective film 6. In such a case, if the end position of the second protective film 7 is shifted by ±5 μm or more, the end of the second protective film 7 has a cross section which is greatly ununiform depending on the position. As a result, such a structure may cause the shaping inaccuracy of the second protective film 7, and the peeling due to such inaccuracy, etc.

It is also not preferable that the end of the second protective film 7 have a structure in which the end thereof is located outside the seal ring 4 (seen from a side closer to the circuit formation region 2). That is because the second protective film 7 having an uniform thickness may not be formed depending on the seal ring 4, the steepness (protruding degree) of the first protective film 6 following the shape of the upper part of the seal ring 4, and the shape of the surface of the first protective film 6.

In view of the above structure, the end of the second protective film 7 is formed so as to be located inside relative to the seal ring 4 when seen from the side closer to the circuit formation region 2, and not to reach the rising portion 8 of the first protective film 6. This structure may be rephrased to the following structure. In other words, of the surface of the first protective film 6, a flat surface located inside relative to the seal ring 4 and substantially covered with the second protective film 7 is referred to as a first surface 6a, a surface located on the seal ring 4 as a second surface 6b, and a surface connecting the first surface and the second surface together as a third surface 6c. In this case, the end of the second protective film 7 is formed so as to be located inside relative to the third surface 6c when seen from the side closer to the circuit formation region 2. In this case, if the end position of the second protective film 7 is shifted by ±5 μm or more, the end of the second protective film 7 is located so as to be the inside relative to of the rising portion 8 (the third surface 6c) by 5 μm or more from the rising portion 8.

The above structure makes it possible to prevent the end of the second protective film 7 from reaching the rising portion 8.

In this way, the second protective film 7 is formed on the flat part of the first protective film 6 located in the circuit formation region 2, thereby making it possible to prevent the shaping inaccuracy, the peeling, etc.

The cap layer 5 is made of, e.g., aluminum (Al). With this material, since aluminum has an oxidation resistance greater than that of copper, the upper most layer of the seal ring 4, i.e., the cap layer 5 has an oxidation resistance greater than that of the sealing layer 4b located directly thereunder. As a result, this can prevent reduced protection of the semiconductor device 50 due to oxidation and corrosion of the seal ring 4.

However, the materials of the cap layer 5, the sealing layer 4b located thereunder, etc., are not limited to the above aluminum and copper. The insulating films 11a, 11b, and 11c constituting the interlayer insulating film 11 are not particularly limited, but they may be, for example, a silicon oxide film (TEOS oxide film) formed using TEOS (tetra ethyl orthosilicate) by a CVD (Chemical Vapor Deposition) method.

### MODIFIED EXAMPLES

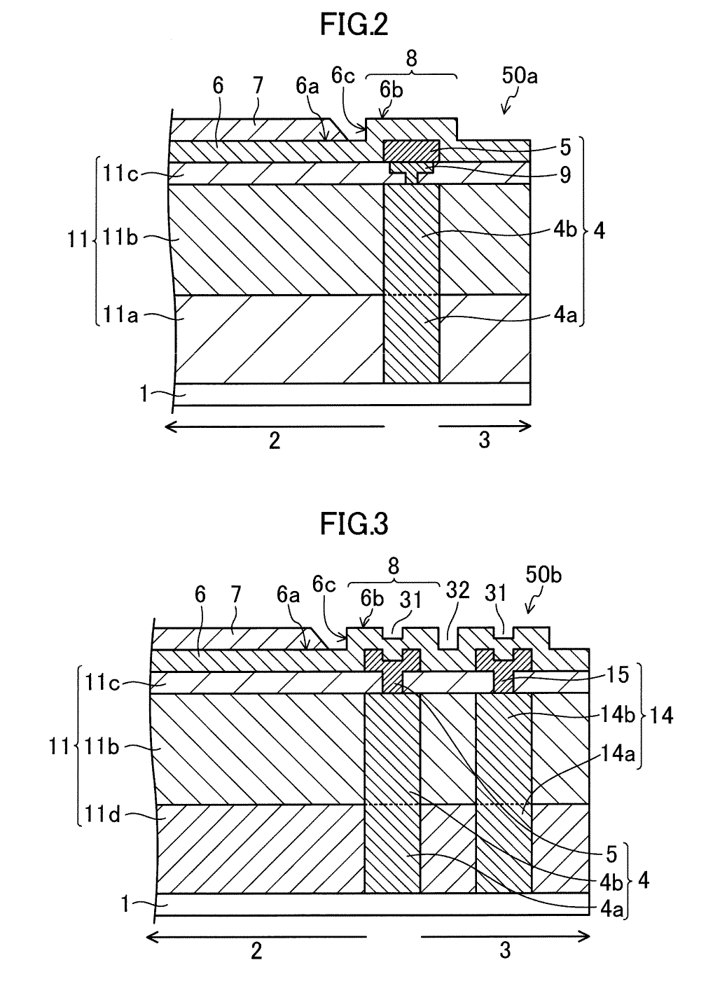

Next, modified examples of the present disclosure will be described. FIG. 2 is a cross-sectional view schematically showing a modified example of a semiconductor device 50a.

Regarding the semiconductor device 50a shown in FIG. 2, the same reference characters as those shown in FIG. 1A are used to represent equivalent elements to those of the semiconductor device 50 shown in FIGS. 1A and 1B, and differences will be described in detail hereinafter.

In the case of the semiconductor device 50 of FIG. 1A, the cap layer 5 made of Al is formed on the sealing layer 4b made of Cu so as to embed the opening provided in the insulating film 11c and to be in contact with the upper surface of the sealing layer 4b. The cap layer 5 protrudes beyond the upper surface of the insulating film 11c.

In contrast, in the case of the semiconductor device 50a, an opening of an insulating film 11c is embedded with a sealing layer 9 made of Cu and formed by a plating method, etc., and the sealing layer 9 is in contact with the upper surface of a sealing layer 4b. Besides, a cap layer 5 made of Al is formed on the insulating film 11c so as to cover the sealing layer 9. The cap layer 5 has a width larger than that of the sealing layer 9, and therefore, it fully covers the upper surface of the sealing layer 9.

Such a structure is particularly effective when the cap layer 5 has an oxidation resistance greater than that of the sealing layer 9 located directly thereunder.

The semiconductor device 50a also has a structure in which a second protective film 7 is located inside relative to the seal ring 4 when seen from a circuit formation region 2 so as not to reach a rising portion 8 of a first protective film 6. This structure obtains a semiconductor device which prevents the shaping inaccuracy and the peeling of the second protective film 7, etc., to have higher reliability.

Next, FIG. 3 is a cross-sectional view schematically showing another modified example of a semiconductor device 50b. Regarding the semiconductor device 50b, the same reference characters as those shown in FIG. 1A are used to represent equivalent elements to those of the semiconductor device 50 shown in FIGS. 1A and 1B, and differences will be described in detail hereinafter.

The semiconductor device 50b includes, in addition to a seal ring 4 equivalent to that in the semiconductor device 50a, a seal ring 14 located outside the seal ring 4 (outside when seen from a side closer to the circuit formation region 2). Hereinafter, the seal ring 4 and the seal ring 14 of the semiconductor device 50b will be hereinafter referred to as a first seal ring 4, and a second seal ring 14, respectively. As well as the first seal ring 4, the second seal ring 14 includes sealing layers 14a and 14b embedded in the interlayer insulating film 11, and a cap layer 15 formed on the sealing layers 14a and 14b to be in contact with the sealing layers 14a and 14b.

An opening 31 is also formed in the first protective film 6 to be located on the second seal ring 14. Besides, an opening 32 is also formed between the first seal ring 4 and the second seal ring 14. The opening 32 formed between the first seal ring 4 and the second seal ring 14 is deeper than the opening 31 located on the seal ring 14.

In this way, the double seal rings surround the circuit formation region 2, thereby making it possible to reliably protect the circuit formation region 2 from water having entered from the cross-section of part of the interlayer insulating film 11, and a crack extension generated by stress. This modified example shows the example of surrounding the circuit formation region 2 by the double seal rings, and triple or more of the seal rings 14 may surround the circuit formation region 2 to further reliably protect the circuit formation region 2.

In view of the foregoing, when a plurality of the seal rings surround the circuit formation region 2, the end of the second protective film 7 is formed to be located inside relative to the rising portion 8 of the first protective film 6 following the shape of the innermost seal ring (the first seal ring 4). This structure obtains a semiconductor device which prevents the shaping inaccuracy and the peeling of the second protective film 7, etc., to have higher reliability.

It is also preferable that an underlying surface (the surface of the first protective film 6) on which the end of the second protective film 7 is located be flat when the plurality of the seal rings are provided.

In the semiconductor device 50b, a low dielectric constant film (low-k film) or an extremely low dielectric constant film (extremely low-k (ELK) film) having a dielectric constant lower than that of the low dielectric constant film (low-k film) is used as an insulating film 11d constituting the interlayer insulating film 11.

A low dielectric constant film (extremely low dielectric constant film) generally has low film density, and therefore, it has high hygroscopicity and high moisture permeability. Therefore, when the low dielectric constant film is used, it is particularly necessary to reduce entry of water to reduce an increase in dielectric constant, deterioration of reliability of interconnects, etc. Similarly, the low dielectric constant film (extremely low dielectric constant film) is mechanically weak, and therefore, it is necessary to prevent a crack extension generated by stress. Therefore, like the semiconductor device 50b, it is effective to provide the plurality of the seal rings to reliably protect the circuit formation region 2.

The low dielectric constant film refers to a film having a low dielectric constant compared to a silicon oxide film (having a dielectric constant of approximately 3.5 to 4.0), and has a dielectric constant of approximately 2.7 to 3.0 (for example, a SiOF film, but is not limited to the SiOF film). The extremely low dielectric constant film refers to a film having a particularly low dielectric constant, and has a dielectric constant of approximately 2.7 or less (for example, a SiCOH film, but is not limited to the SiCOH film).

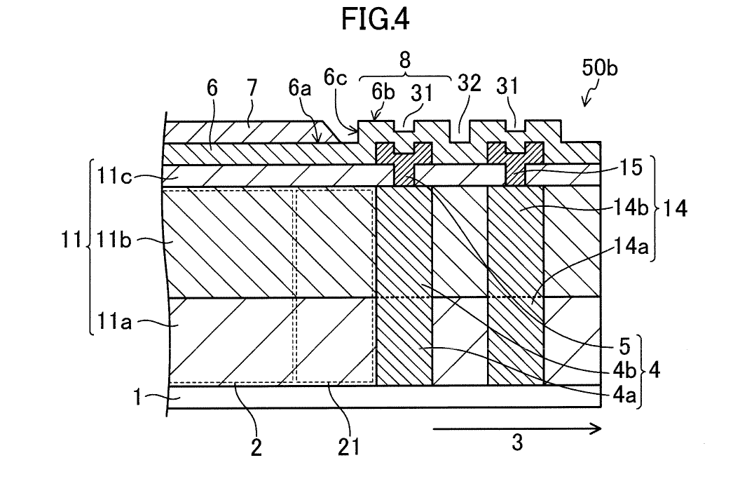

Furthermore, as shown in FIG. 4, a separation region 21 including no circuits, interconnects, etc., may be provided between the innermost seal ring (the first seal ring 4) and the circuit formation region 2, and the end of the second protective film 7 may be formed to be located on part of the first protective film 6 having a flat upper surface in the separation region 21. With such a structure, the first seal ring 4 and the circuit formation region 2 are separated from each other, and therefore, the circuit formation region 2 can be reliably protected from water having entered from the cross-section of part of the interlayer insulating film 11, and a crack extension generated by stress. A flat region can be widely secured to locate the end of the second protective film 7, thereby making it possible to form the second protective film 7 without shape variations even if the second protective film 7 is formed by a method such that the end of the second protective film 7 is not accurately positioned. FIG. 4 shows a case where a plurality of the seal rings are provided, and it is also possible to provide the separation region 21 when only one seal ring is provided.

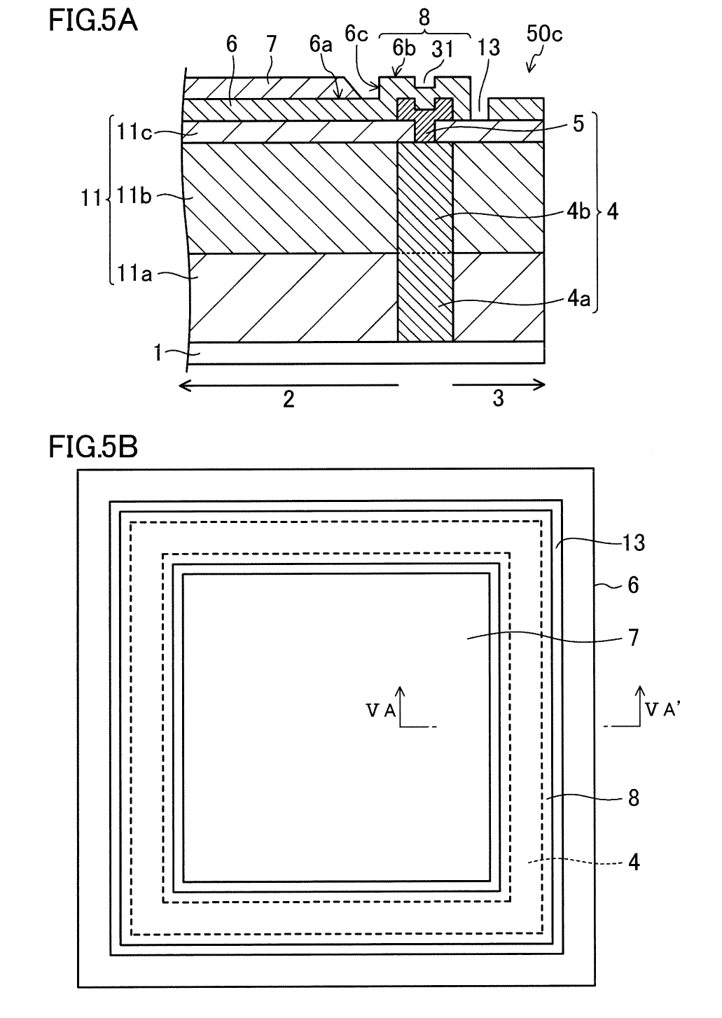

Next, FIGS. 5A and 5B show are, respectively, a cross-sectional view and a plan view schematically showing schematically showing another modified example of a semiconductor device 50c. FIG. 5A is the cross-sectional view taken along the line Va-Va′ of FIG. 5B.

Regarding the semiconductor device 50c, the same reference characters as those shown in FIGS. 1A and 1B are used to represent equivalent elements to those of the semiconductor device 50 shown in FIGS. 1A and 1B, and differences will be described in detail hereinafter.

According to the semiconductor device 50c, an opening 13 is formed in the first protective film 6 outside the seal ring 4 (outside when seen from a side closer to the circuit formation region 2). This structure can block a route of a transmission of impact, stress, etc., toward the circuit formation region 2 from the outside at a time of dicing of a wafer. In other words, if the opening 13 does not exist, impact, stress, etc., is transmitted to the circuit formation region 2 through the first protective film 6 as a transmission. However, providing the opening 13 can block such impact, stress, etc. In particular, if the opening 13 is formed so as to pass through the first protective film 6, impact, stress, etc., are less likely to be transmitted, thereby improving the advantage of protecting the circuit formation region 2. As well as the opening 13, the openings 31 and 32 can be expected to relieve the stress.

However, it is preferable that the opening 13 do not reach the inside of part of the interlayer insulating film 11 located directly under the first protective film 6. In other words, if the opening 13 is formed so as to remove part of upper part of the interlayer insulating film 11, the interconnects, etc., provided inside the interlayer insulating film 11 may be exposed, and therefore, the exposure is preferably avoided.

The exposure is preferably avoided since, for example, other interconnects for inspection can be provided outside the seal ring. If the opening 13 reaches the inside of the part of the interlayer insulating film 11, the sealing layer constituting the seal ring may be exposed depending on the width of the opening 13, etc. Such exposure is also preferably avoided.

It is preferable that the opening 13 be formed in a closed loop pattern (linked, closed frame pattern) when the semiconductor device 50c is seen in plan view. FIG. 5B shows an example of a closed rectangular surrounding the outside of the seal ring 4 (the outside of the rising portion 8 of the first protective film 6). Such a structure can block the route of the transmission of impact, stress, etc., from any directions to the circuit formation region 2, thereby reliably improving the advantage of protection.

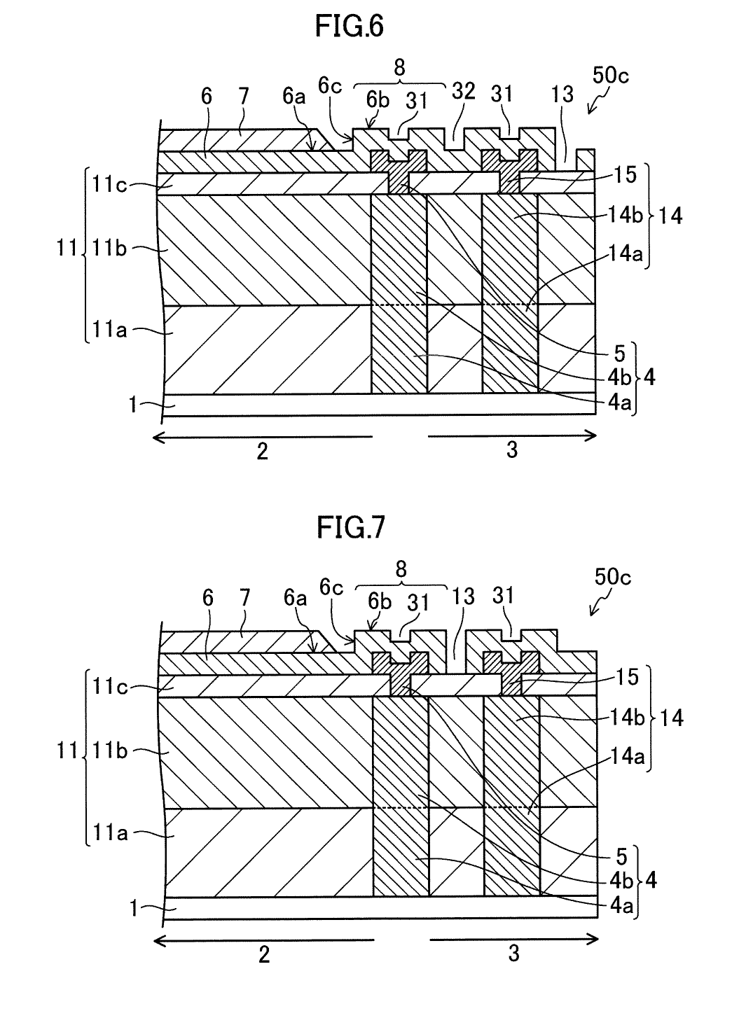

The opening 13 can also be provided when a plurality of the seal rings are provided. For example, the structure of FIG. 6 has the first seal ring 4 and the second seal ring 14 as well as the example of FIG. 3, and the opening 13 is provided outside the second seal ring 14. In the structure of FIG. 7, the opening 13 is provided outside the innermost seal ring 4. In the structure of FIG. 8, the opening 13 is provided between the first seal ring 4 and the second seal ring 14, and the opening 13 is provided outside the second seal ring 14.

As stated above, in the various structures as exemplified in FIGS. 5A, 5B, 6, 7, and 8, the end of the second protective film 7 is located inside relative to the seal ring 4 (inside relative to the innermost first seal ring 4 when a plurality of the seal rings are provided), and does not reach the rising portion 8 of the first protective film 6 having a shape following the upper part of the seal ring 4. Such structures can secure shaping accuracy and peel resistance of the second protective film 7, etc., thereby achieving a semiconductor device having higher reliability.

In particular, when only one seal ring having the opening 13 is formed (the example of FIGS. 5A and 5B), and the opening 13 is formed outside the innermost seal ring (the examples of FIGS. 7 and 8), if the end of the second protective film 7 is provided to be located outside the (first) seal ring 4, the shape inaccuracy of the second protective film 7 and the peeling due to such shape inaccuracy are more likely to occur. In other words, depending on the dimension of each part, and the poor positioning accuracy of the end position, etc., the end of the second protective film 7 may be located on the opening 13, and as a result, the end of the second protective film 7 is more likely to be inaccurately formed. Therefore, such a case can more significantly achieve the advantage by the end of the second protective film 7 which is located inside relative to the (first) seal ring 4.

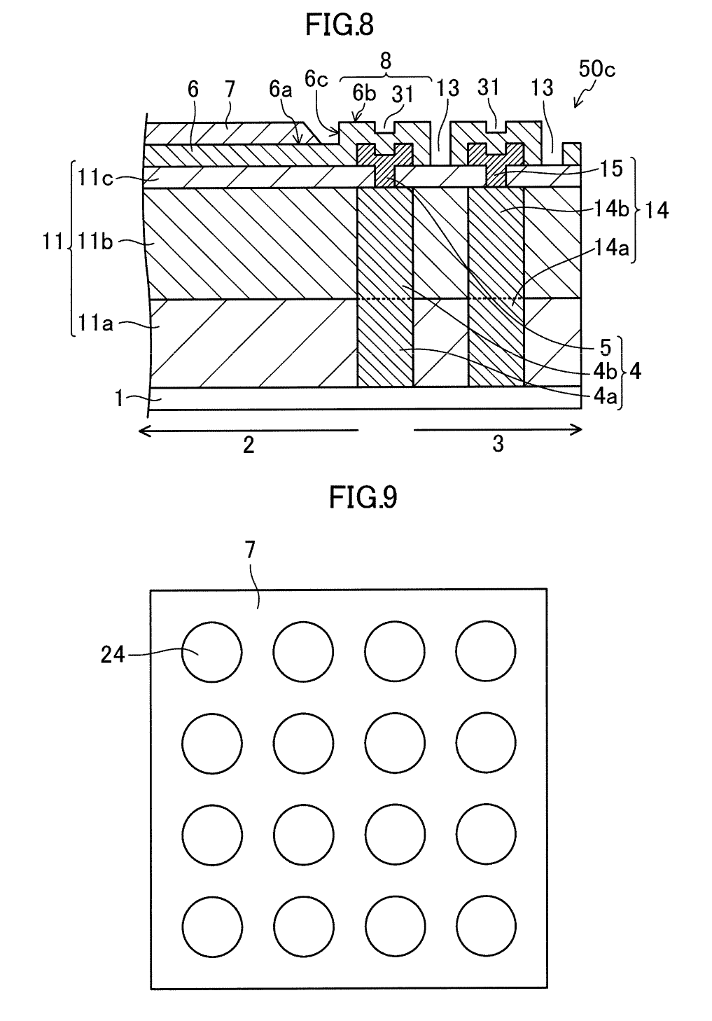

In the circuit formation region 2 of the semiconductor device having the seal ring and the protective film exemplified with the drawings, as shown in, e.g., FIG. 9, a plurality of bumps 24 (sixteen bumps in this example) can be arranged in a grid pattern (a matrix pattern). Such an arrangement of the bumps 24 can provide many bumps 24 in the circuit formation region 2 having a limited area. The bump 24 is made of, e.g., a Sn—Ag based lead-free solder material. However, the material of the bump is not limited to the above material, and may be a Sn—Cu based solder material, Sn—Cu—Ni based solder material, etc., or may be another material.

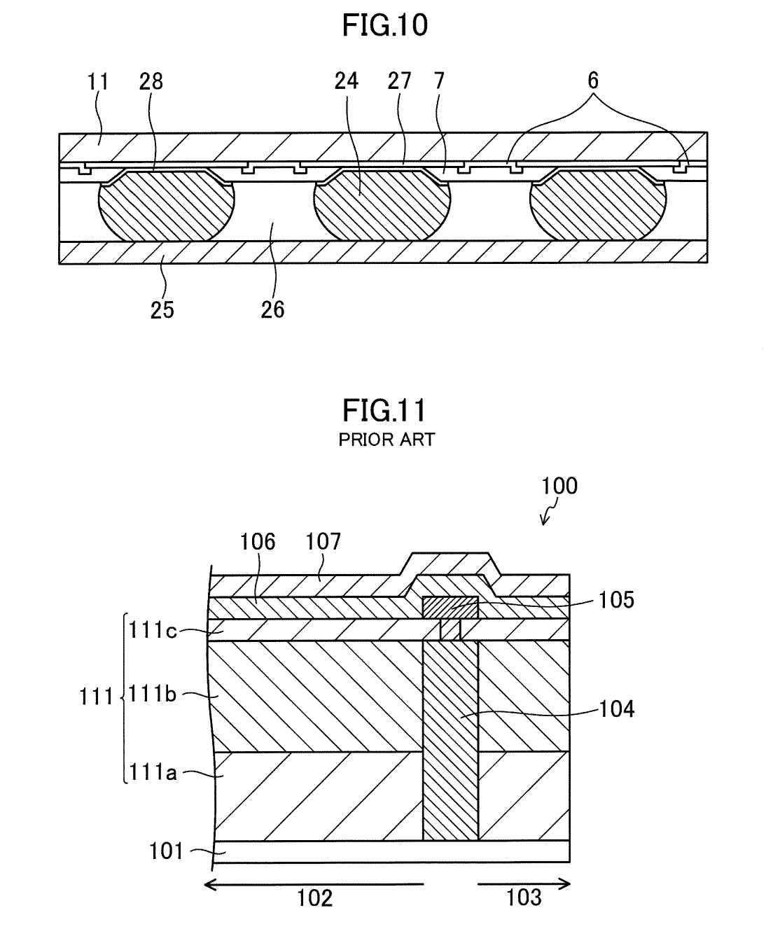

Each interval for arranging the bumps 24 is, e.g., 160 μm. When the bumps 24 are arranged in such a pattern, they are flip-chip mounted on an organic substrate 25, etc. to contribute to high-density packaging of the semiconductor device, as exemplified in FIG. 10. In FIG. 10, the semiconductor device 50, etc., is shown such that the element in which the protective film is formed faces downward, and the illustration of the semiconductor substrate 1 is omitted.

As shown in FIG. 10, an electrode pad 27 is formed in the lower part of the bump 24 formed in the semiconductor device. The electrode pad 27 is made of, e.g., aluminum, and the first protective film 6 and the second protective film 7 on the interlayer insulating film 11 are provided in a region where the first protective film 6 and the second protective film 7 are not formed. In the interlayer insulating film 11, interconnects, etc., connected to the electrode pad 27 are provided, and the illustration of which is not omitted.

Furthermore, an under barrier metal 28 (UBM) is provided between the bump 24 and the electrode pad 27. In general, the under barrier metal 28 is formed as a metal layer for supporting a bond strength between the electrode pad 27 and the bump 24 formed thereon. The material of the under barrier metal 28 is, e.g., nickel (Ni), but is not limited to nickel.

A space between the semiconductor device which is flip-chip mounted and the organic substrate 25 is filled with an underfill. The underfill 26 prevents moisture and dust, etc., from the outside, relieves stress due to warp of the organic substrate 25, etc., and secures connection reliability. The underfill 26 is made of, e.g., a thermosetting liquid encapsulant, and more specifically, it may be made of an epoxy resin, a curing agent, a filler, etc.

According to the techniques of the present disclosure, a semiconductor device having a seal ring and a protective film can be obtained to secure shaping accuracy and peel resistance to improve higher reliability, and therefore, the present disclosure is also useful for flip-chip packages, etc., in which chips are flip-chip mounted on a substrate through an underfill.

1. A semiconductor device, comprising:
a substrate having a circuit formation region;
an interlayer insulating film formed on the substrate;
a first seal ring formed in the interlayer insulating film to surround the circuit formation region;
a first protective film formed on the interlayer insulating film in the circuit formation region and on the first seal ring; and
a second protective film formed on the first protective film and inside relative to the first seal ring,
wherein
the first protective film has a first surface contacting the second protective film, a second surface located directly on the first seal ring, and a third surface connecting the first surface and the second surface together, and
an end of the second protective film is located inside relative to the third surface.

2. The semiconductor device of claim 1, wherein
a first opening is formed in the first protective film to be located directly on the first seal ring.

3. The semiconductor device of claim 2, wherein
a second opening is formed in the first protective film to be located outside the first seal ring.

4. The semiconductor device of claim 3, further comprising
at least one second seal ring formed in the interlayer insulating film to surround the first seal ring.

5. The semiconductor device of claim 4, wherein
the second opening is located between the first seal ring and the at least one second seal ring.

6. The semiconductor device of claim 3, wherein
the second opening is formed to pass through the first protective film.

7. The semiconductor device of claim 4, wherein
the second opening is formed so as not to reach part of the interlayer insulating film located directly under the first protective film.

8. The semiconductor device of claim 4, wherein
the second opening is located to surround the first seal ring.

9. The semiconductor device of claim 8, wherein
the second opening is located to continuously surround the first seal ring.

10. The semiconductor device of claim 1, wherein
a first opening is formed in the first protective film to be located directly on the first seal ring,
a second opening is formed in the first protective film to be located outside the first seal ring, and
the second opening is deeper than the first opening.

11. The semiconductor device of claim 4, wherein
a third opening is formed in the first protective film to be located outside the second seal ring.

12. The semiconductor device of claim 11, wherein
the third opening is deeper than the second opening.

13. The semiconductor device of claim 11, wherein
the second opening is deeper than the third opening.

14. The semiconductor device of claim 4, wherein
the second seal ring is an outermost seal ring.

15. The semiconductor device of claim 4, wherein
an opening is located directly on each of the first seal ring and the at least one second seal ring in the first protective film.

16. The semiconductor device of claim 1, wherein
the first seal ring includes a plurality of sealing layers which are stacked, and a cap layer formed on an uppermost sealing layer to be connected thereto.

17. The semiconductor device of claim 16, wherein
a width of the cap layer is wider than that of the uppermost sealing layer.

18. The semiconductor device of claim 16, wherein
the sealing layer is made of copper, and
the cap layer is made of aluminum.

19. The semiconductor device of claim 1, wherein
the end of the second protective film is located between the third surface and the circuit formation region.

20. The semiconductor device of claim 1, wherein
part of the first protective film on which the end of the second protective film is located has an upper surface which is substantially flat.

21. The semiconductor device of claim 1, further comprising
a separation region between the first seal ring and the circuit formation region so as not to form a circuit and an interconnect therein, wherein
an upper surface of part of the first protective film located in the separation region is substantially flat, and
the end of the second protective film is located on the separation region.

22. The semiconductor device of claim 1, wherein
the interlayer insulating film includes a low dielectric constant film.

23. The semiconductor device of claim 1, wherein
the interlayer insulating film includes an extremely low dielectric constant film.

24. The semiconductor device of claim 1, further comprising
a plurality of bumps arranged in a grid pattern on a back surface of the substrate and under the circuit formation region.

25. The semiconductor device of claim 24, wherein
the bumps are arranged only under the circuit formation region, and not arranged under the seal ring.

26. The semiconductor device of claim 1, wherein
the first protective film is made of a silicon nitride film, and
the second protective film is made of a polyimide film.

27. The semiconductor device of claim 1, wherein
a surface of the second protective film is located to be higher than the second surface of the first protective film.

28. A flip-chip package, wherein
the semiconductor device of claim 1 is flip-chip mounted on a mounting substrate.
